(19) United States
(12) Patent Application Publication
(10) Pub. No.: US 2015/0296632 A1
(43) Pub. Date: Oct. 15, 2015

(54) METAL-FOIL-ATTACHED ADHESIVE SHEET, METAL-FOIL-ATTACHED LAMINATED BOARD, METAL-FOIL-ATTACHED MULTI-LAYER BOARD, AND METHOD OF MANUFACTURING CIRCUIT BOARD

(71) Applicant: Panasonic Intellectual Property Management Co., Ltd., Osaka (JP)

(72) Inventors: Kentaro FUJINO, Fukushima (JP); Noriko ONUMA, Fukushima (JP); Rihoko TOMBE, Fukushima (JP)

(21) Appl. No.: 14/674,930

(22) Filed: Mar. 31, 2015

(30) Foreign Application Priority Data
Apr. 11, 2014 (JP) 2014-081761

(51) Int. Cl. H05K 3/46; H05K 1/09

(52) U.S. Cl. CPC H05K 3/4655; H05K 3/4661; H05K 1/09

(57) ABSTRACT

A metal-foil-attached adhesive sheet includes a metal foil, a release layer provided on the metal foil, and an adhesive layer provided on the release layer and made of a thermosetting resin composition which is semi-cured. A peeling strength P1 at an interface between the metal foil and the release layer and a peeling strength P2 at an interface between the release layer and the adhesive layer after curing satisfy P1>P2.

### TECHNICAL FIELD

The present disclosure relates to a metal-foil-attached adhesive sheet, a metal-foil-attached laminated board and a metal-foil-attached multi-layer board, each of which is used for manufacturing a circuit board, and a method of manufacturing a circuit board using the same.

### BACKGROUND ART

In recent years, as a method of manufacturing a multi-layer printed wiring board, a manufacturing technique using a build-up method has received attention in which resin layers and conductor layers are alternately stacked on a conductor layer of an inner-layer circuit board to form a multi-layer printed wiring board.

The build-up method will be described below. For example, a surface of an inner-layer circuit board or an uncladded board as a core board is provided with a resin-attached copper foil with a resin layer, which is composed of a thermosetting resin composition etc. in a B stage state, formed on one surface of a copper foil, or an adhesive sheet with a resin layer, which is composed of a thermosetting resin composition etc. in a B stage, formed on one surface of a support such as a polyester film. A resin-attached copper foil or an adhesive sheet is stacked, the resin layer is cured, and a wiring pattern is then formed on a surface of the resin layer after curing. This process is repeated one or more times to manufacture a multi-layer printed wiring board. Conventional methods similar to the above-mentioned method are described in, for example, Japanese Patent Laid-Open Publication No. 2002-353583 and Japanese Patent No. 4992396.

In the method using the resin-attached copper foil, resin-attached copper foils are laminated with a core board, a prepreg or the like to perform batch lamination/forming, and the outermost copper foil is subjected to etching processing to form a wiring pattern, thereby manufacturing a multi-layer printed wiring board (see, for example, Japanese Patent Lid-Open Publication No. 2002-353583).

In recent years, the demand for making finer wiring patterns in the multi-layer wiring board has increased, and, for example, it has been required to form a fine wiring pattern in which a line-and-space (L/S) which is the ratio of a width L of a line to a width S of a space between lines is not larger than 20 μm/20 μm.

On the other hand, in the manufacturing method using the resin-attached copper foil, the outermost copper foil is subjected to etching processing to form a pattern, and therefore it is difficult to provide a fine wiring pattern as described above. There is also a method in which rather than forming a pattern by etching processing as described above, a copper foil is once entirely removed to expose a cured resin layer, and then by making use of irregularity traces on a mat surface of the copper foil remaining on a surface of the resin layer, plating processing is performed by a semi-additive method or the like to form a fine wiring pattern. Even in this method, it is required to perform an etching process, thus causing an increase in manufacturing cost. The wiring pattern cannot be sufficiently fine to obtain the line-and-space (L/S) not larger than 10 μm/10 μm.

On the other hand, the method using the adhesive sheet receives attention as a manufacturing method capable of providing a fine wiring pattern. In the method using the adhesive sheet, the adhesive sheet is stacked on a surface of a core board, a support is then peeled, and further, heating is performed to cure a resin layer transferred onto the core board. A surface of the resin layer after curing is roughened with an oxidant, such as potassium permanganate, and plated by a semi-additive method or the like to form a wiring pattern, thereby manufacturing a multi-layer printed wiring board (see, for example, Japanese Patent No. 4992396). By the method using the adhesive sheet, wiring can be fine to obtain the line-and-space (L/S) not larger than 10 μm/10 μm. In this case, however, since a resin film is generally used as the support of the adhesive sheet, batch lamination/forming that requires a forming temperature higher than 160° C. cannot be performed, and it is required to perform the foregoing lamination method. Therefore, for curing an uncured resin layer transferred onto the core board through lamination, a step of heating and curing is required later, thus increasing manufacturing costs.

### SUMMARY

A metal-foil-attached adhesive sheet includes a metal foil, a release layer provided on the metal foil, and an adhesive layer provided on the release layer and made of a thermosetting resin composition which is semi-cured. A peeling strength P1 at an interface between the metal foil and the release layer and a peeling strength P2 at an interface between the release layer and the adhesive layer after curing satisfy P1>P2.

### BRIEF DESCRIPTION OF DRAWINGS

FIG. 1A is a schematic sectional view of a metal-foil-attached adhesive sheet in accordance with an exemplary embodiment.

FIG. 1B is a schematic plan view of a test piece of the metal-foil-attached adhesive sheet for measuring a peeling strength in accordance with the embodiment.

FIG. 1C is a schematic front view of a metal-foil-attached adhesive sheet for measuring a peeling strength of the test piece.

FIGS. 2A to 2D are schematic sectional views of a circuit board in accordance with the embodiment for illustrating a method of manufacturing the circuit board.

FIGS. 3A to 3D are schematic sectional views a circuit board in accordance with the embodiment for illustrating another method of manufacturing the circuit board.

FIGS. 4A to 4D are schematic sectional views a circuit board in accordance with the embodiment for illustrating still another method of manufacturing the circuit board.

### DETAIL DESCRIPTION OF PREFERRED EMBODIMENT

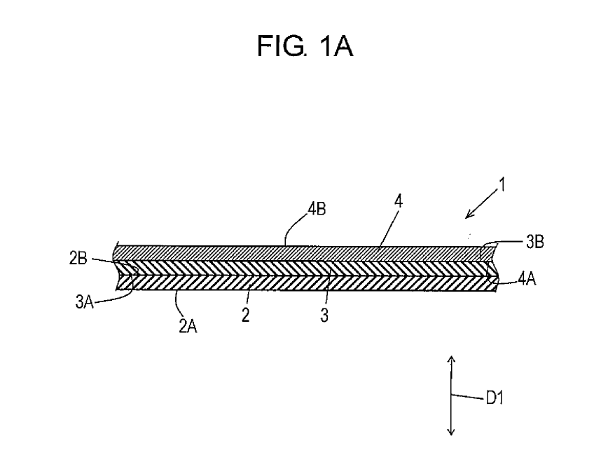

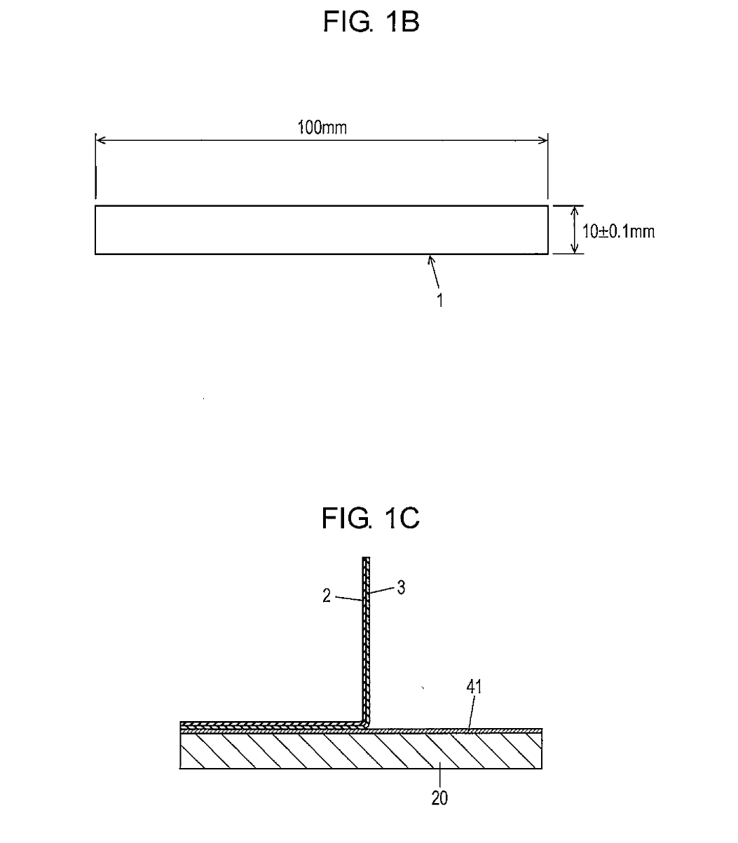

FIG. 1A is a schematic sectional view of metal-foil-attached adhesive sheet 1 in an exemplary embodiment. Metal-foil-attached adhesive sheet 1 includes metal foil 2, release layer 3 and adhesive layer 4. Metal foil 2, release layer 3 and adhesive layer 4 are stacked in this order in lamination direction D1. Metal layer 2 has surfaces 2A and 2B opposite to each other. Release layer 3 has surface 3A provided on surface 2B of metal foil 2, and has surface 3B opposite to surface 3A. Adhesive layer 4 has surface 4A provided on surface 3B of release layer 3, and has surface 4B opposite to surface 4A.

Examples of metal foil 2 may include a copper foil, an aluminum foil, a silver foil, a brass foil, a stainless foil, a nickel foil, and a nichrome foil. The thickness of metal foil 2, a dimension of metal foil 2 in lamination direction D1, ranges e.g., from 12 μm to 35 μm. At least surface 2B out of surfaces 2A and 2B of metal foil 2 is preferably a mat surface. Since metal foil 2 and release layer 3 have a certain level of adhesive strength, surface 2B of metal foil 2 on which release layer 3 is provided is preferably a mat surface. Surface 2B of metal foil 2 on which release layer 3 is provided has a ten-point roughness Rz preferably ranging from 0.5 μm to 2.0 μm, more preferably, from 0.5 μm to 1.0 μm. The ten-point average roughness Rz not smaller than 0.5 μm provides proper adhesive strength between surface 2B of metal foil 2 and surface 3A of release layer 3 by an anchor effect. The ten-point average roughness Rz not larger than 2.0 μm prevents an irregular shape of surface 2B of metal foil 2 from affecting surface 3B of release layer 3 and surface 4A of adhesive layer 4.

Release layer 3 is provided on surface 2B of metal foil 2 as described above. Release layer 3 preferably contains a matrix resin and a silicone compound.

The matrix resin functions as a binding element for forming a film that constitutes release layer 3. Examples of resins that can be contained in the matrix resin may include thermosetting resins, thermoplastic resins and ultraviolet-ray-curable resins. Specific examples of the matrix resin may include epoxy resins, phenol resins, imide resins, (meth)acrylic resins, cyanate ester resins, urea resins, diallyl phthalate resins, melamine resins, unsaturated polyester resins, polyurethane resins, aminoalkyd resins, silicon resins and polysiloxane resins. Among the resins, epoxy resins preferably have heat resistance and a proper binding property. The matrix resin may further contain a curing agent, a curing accelerator, a crosslinker and a polymerization initiator as necessary with the above-mentioned resin as a main component. The matrix resin is cured after release layer 3 is formed.

The silicone resin exists in a state of being mixed with the matrix resin in release layer 3, and has a function of providing the release layer with releasability. The silicone compound is not particularly limited as long as the compound has the function of providing the layer with releasability, but the compound properly compatible and mixable with the matrix resin is preferable. That is, the silicone compound generally has strong hydrophobicity, and therefore, is hardly compatible with the matrix resin based on an organic resin, so that phase separation may occur, for example, in preparation of a varnish. Thus, the silicone compound preferably has a silicone structural unit and an organic resin structural unit in one molecule. Examples of the silicone compound include polymer compounds with a molecular structure having the organic resin structural unit as a main chain and having the silicone structural unit on a side chain thereof, and polymer compounds with a molecular structure having the silicone structural unit as a main chain and having the organic resin structural unit on a side chain thereof. When one having the above-mentioned molecular structure is used as the silicone compound, the organic resin structural unit enters in the phase of the matrix resin, so that proper compatibility is achieved, and a part of the silicone structural unit appears on surface 3B of release layer 3 to provide proper releasability. The organic resin structural unit preferably has in its structure an ester bond or a polar group such as a hydroxyl group, or has a functional group having reactivity with a thermosetting resin component, such as an epoxy resin, that forms the matrix resin. This provides more proper compatibility between the silicone compound and the matrix resin. Specific examples of the silicone compound include those represented by Chemical Formula 1. The silicone compound represented by Chemical Formula 1 has improved hydrophilicity owing to the structure of substituent A, and is therefore easily compatible with the matrix resin, so that phase separation can be suppressed.

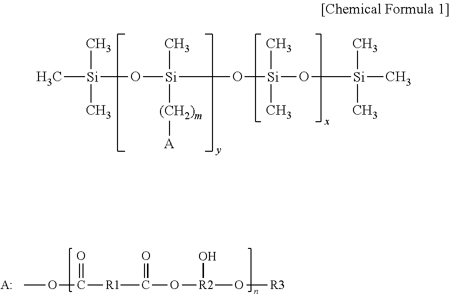

In Chemical Formula 1, each of m, n, x and y represents the number of bracketed repeating units. Each of m, n and y represents an integer not smaller than one, and x represents an integer not smaller than zero. Each of R1 and R2 represents an aliphatic compound group containing one or more carbon atoms. R3 represents an alkyl group.

The content of the silicone compound preferably ranges from 5.0 wt. % to 40.0 wt. % with respect to the whole amount of release layer 3. When the content of the silicone compound is not smaller than 5.0 wt. %, release layer 3 can be easily peeled from adhesive layer 4 after curing adhesive layer 4. When the content of the silicone compound is smaller than 40.0 wt. %, a thermosetting resin composition for forming adhesive layer 4 may be prevented from being repelled on surface 3B during application of the thermosetting resin composition onto surface 3B of release layer 3. Adhesion required at an interface between surface 3B of release layer 3 and surface 4A of adhesive layer 4 which is semi-cured can be secured.

The matrix resin and the silicone compound are uniformly mixed with each other without being phase-separated or localized in release layer 3. The silicone compound distributed uniformly in release layer 3, as described above, prevents adhesion between release layer 3 and metal foil 2 and adhesion between release layer 3 and adhesive layer 4 from being locally changed.

Release layer 3 has a softening point preferably not lower than 150° C. Lamination/forming at once is generally performed at a temperature lower than 150° C. Therefore, the softening point of release layer 3 not lower than 150° C. prevents release layer 3 from being softened and from deforming during heat and pressure forming for the lamination/forming. Release layer 3 can be easily peeled from adhesive layer 4 after curing adhesive layer 4. The thickness of adhesive layer 4 can be prevented from changing when adhesive layer 4 is cured. The smoothness of surface 4A of adhesive layer 4 can be secured when adhesive layer 4 is cured.

The thickness of release layer 3, i.e., a dimension thereof in lamination direction D1, preferably ranges from 0.5 μm to 5.0 μm, more preferably, from 1.0 μm to 3.0 μm. Release layer 3 can be easily peeled from adhesive layer 4 after curing adhesive layer 4. The thickness of release layer 3 is preferably larger than the ten-point average roughness Rz of surface 2B of metal foil 2 on which release layer 3 is provided. Surface 3B of release layer 3 on the adhesive layer 4 can be smooth, and therefore, the smoothness of surface 4A of adhesive layer 4 after curing can be secured.

Adhesive layer 4 will be described below. Adhesive layer 4 is provided on surface 3B of release layer 3. Adhesive layer 4 is made of a thermosetting resin composition which is semi-cured. The semi-cured state of adhesive layer 4 can be appropriately adjusted by, e.g. preheating according to a purpose, and is preferably a state in which the cure degree is relatively high rather than a state close to an uncured state. When the semi-cured state of adhesive layer 4 is a semi-cured state in which the cure degree is relatively high, resin flow during heat forming can be suppressed to easily secure a desired thickness of adhesive layer 4 after curing. The tackiness of the surface of adhesive layer 4 in a semi-cured state can also be suppressed to improve the handling property. A protective film can be provided on surface 4B of adhesive layer 4 of metal-foil-attached adhesive sheet 1.

In adhesive layer 4, the resin component that forms the thermosetting resin composition is not particularly limited, and the thermosetting resin composition can be prepared by, for example, blending a curing agent, a curing accelerator and the like in a thermosetting resin. A filler, a thermoplastic resin, a flame retardant and the like can be blended in the thermosetting resin as necessary.

Examples of the thermosetting resin include epoxy resins, cyanate ester resins, polyfunctional maleimide resins, unsaturated polyphenylene ether resins, benzoxazine resins and vinyl ester resins. These thermosetting resins may be used alone, or may be used in combination of two or more of the thermosetting resins.

The curing agent may be appropriately selected according to a kind of the thermosetting resin. For example, when the thermosetting resin contains an epoxy resin, examples of the curing agent may include diamine-based curing agents such as first amine and second amine, di- or more functional phenolic curing agents, acid anhydride-based curing agents, dicyandiamide and low-molecular-weight polyphenylene ether compounds. These curing agents may be used alone, or may be used in combination of two or more of the curing agents.

Examples of the curing accelerator include imidazole-based compounds, tertiary amine-based compounds, organic phosphine compounds and metal soap.

As the filler, an inorganic filler or an organic filler can be used.

Examples of the inorganic filler include metal oxides such as silica, aluminum oxide, magnesium oxide and titanium oxide, metal hydroxides such as aluminum hydroxide and magnesium hydroxide, barium sulfate, calcium carbonate, magnesium carbonate, boron nitride, aluminum borate, barium titanate, strontium titanate, calcium titanate, magnesium titanate, bismuth titanate, talc, clay and mica powders. Among them, silica is particularly suitable.

Examples of the organic filler include cured resin powders, acrylic rubber particles, core-shell-type rubber particles, crosslinked acrylonitrile-butadiene rubber particles and crosslinked styrene-butadiene rubber particles.

These fillers may be used alone, or may be used in combination of two or more of the fillers. The filler has an average particle size preferably not larger than 1 μm, more preferably not larger than 0.8 μm, especially preferably not larger than 0.7 μm for forming a conductor layer which has high adhesion by plating on a surface of adhesive layer 4 after curing adhesive layer 4. According to the embodiment, the average particle size is a weight average particle size measured using a laser diffraction particle size analyzer.

Examples of the thermosetting resin include acryl resins, phenoxy resins, polyvinyl acetal resins, high-molecular-weight polyphenylene ether resins and carbodiimide resins. The thermosetting resin may be appropriately selected while compatibility with the thermosetting resin or curing agent and solubility in a varnish preparing solvent are taken into consideration.

Here, the thermosetting resin composition preferably has a low-roughness surface to be easily formed by subjecting a surface of adhesive layer 4 after curing to roughening processing. Thereby, a fine wiring pattern etc. is easily formed on the surface by plating the surface, and the adhesion of the conductor layer (metal conductor layer) that forms the wiring pattern is improved. That is, such a thermosetting resin composition is suitable for forming a fine wiring pattern by plating a surface of cured adhesive layer 4 by a semi-additive method or the like.

The thermosetting resin composition is not particularly limited. An example of thermosetting resin may include the epoxy resin composition described in Japanese Patent No. 4600359. The epoxy resin composition contains three components: (A) an epoxy resin having an average epoxy equivalent ranging from 150 to 400; (B) an epoxy resin that is a bisphenol A-type epoxy resin having an average epoxy equivalent ranging from 450 to 500; and (C) a phenolic novolac resin having a triazine ring. The ratio of the mass of component (B) to the mass of component (A) ranges from 4.2 to 9.

In the epoxy resin composition, component (A) forms a cured part having a high crosslinking density when cured, and component (B) forms a cured part having a low crosslinking density when cured. When curing is performed using component (C) as a curing agent, and the surface of adhesive layer 4 is subjected to roughening processing, the part having a high crosslinking density is hard to be dissolved, and the part having a low crosslinking density is easily dissolved, so that the part having a low crosslinking density is preferentially dissolved to form a deep recess, and the part having a high crosslinking density is slowly and moderately dissolved.

It is considered that by blending component (A) and component (B) at the ratio of the mass of the latter to the mass of the former ranging from 4.2 to 9, surface 4A which has a small surface roughness but has a high irregularity density (a large number of irregularities per unit surface area) is formed to increase the surface area, so that the contact area with the conductor layer increases, and provides high adhesion with the conductor layer.

It is considered that by using a brominated bisphenol A-type epoxy resin is used as component (B), an incompletely cured part is easily generated with bromine atoms causing steric hindrance in curing. When the cured material is subjected to roughening processing, this part is dissolved so as to form particularly fine irregularities, thereby providing high adhesion.

Here, it is preferred that a difference between the average epoxy equivalent of component (A) and the average epoxy equivalent of component (B) is larger than 260 since a roughened surface particularly excellent in adhesion can be formed. In the epoxy resin composition, component (C) is preferably a cresol-based novolac resin having a triazine ring. This configuration ensures further satisfactory adhesion with the conductor layer. Further, when the epoxy resin composition contains an inorganic filler having an average particle size not larger than 1 μm, adhesion with the conductor layer can be further improved while the surface roughness of adhesive layer 4 after curing is maintained low.

Specific examples of component (A) may include bisphenol A-type epoxy resins, bisphenol F-type epoxy resins, bisphenol S-type epoxy resins, biphenyl-type epoxy resins, alicyclic epoxy resins, phenolic novolac-type epoxy resins including diglycidyl ether compounds of polyfunctional phenols, diglycidyl ether compounds of polyfunctional alcohols and diglycidyl ether compounds of polycondensates of phenols and formaldehyde, cresol novolac-type epoxy resins, bisphenol A novolac-type epoxy resins, and epoxy resins obtained by brominating these resins. As component (A), only one of these resins may be used, or two or more of these resins may be used in combination. Among them, phenolic novolac-type epoxy resins are preferred as component (A) since reactivity is high.

As component (A) and component (B), it is preferred to select a combination of epoxy resins in which a difference between the average epoxy equivalent of component (A) and the average epoxy equivalent of component (B) is larger than 260. When the difference in average epoxy equivalent is excessively small, a difference in solubility in a roughening agent between cured parts formed by component (A) and component (B) and having different crosslinking densities is insufficient. When the difference in average epoxy equivalent is excessively large, a difference in crosslinking density is excessively large, so that it tends to be difficult to form a roughened surface excellent in balance between surface roughness and adhesion.

The phenolic novolac resin having a triazine ring, as component (C), is a phenolic novolac resin containing a structural unit derived from a compound having a triazine ring. Examples of the phenolic novolac resin having a triazine ring may include those represented by the general formula of chemical formula 2.

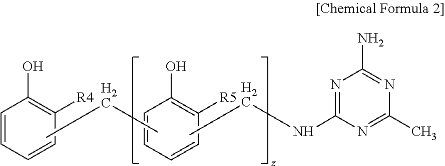

In chemical formula 2, each of R4 and R5 represents a methyl group or a hydrogen atom, and z is an integer ranging from one to five and represents the number of the bracketed repeating units.

Preferably, the blended amount of component (C) is adjusted so that the ratio of the hydroxyl group equivalent of component (C) to the average epoxy equivalent of the sum of component (A) and component (B) ranges from 0.3 to 0.7. In the epoxy resin composition, it is preferred to select a kind of component (C) so that the content of nitrogen derived from component (C) ranges from 1 wt. % to 5 wt. % with respect to the whole amount of the epoxy resin composition. When the nitrogen content ranges from 1 wt. % to 5 wt. %, a dense and uniform roughened surface is obtained after roughening processing. As the phenolic novolac resin having triazine rings having different nitrogen contents, for example, “PHENOLITE Series” products manufactured by Dainippon Ink & Chemicals, Inc., such as “PHENOLITE LA 1356” (nitrogen content: 19%), “PHENOLITE LA 3018” (nitrogen content: 18%) and “PHENOLITE EXB 9851” (nitrogen content: 8%) may be used.

The epoxy resin composition may contain a curing accelerator, such as imidazoles (e.g., 2-methyl imidazole), tertiary amines (e.g., triethylene diamine), or organic phosphines (e.g., triphenyl phosphine), for accelerating the curing reaction.

The epoxy resin composition may further contain an inorganic filler, such as silica. The blended amount of the inorganic filler preferably ranges from 5 wt. % to 50 wt. % with respect to the whole amount of the epoxy resin composition. The inorganic filler has an average particle size preferably not larger than 1 μm, more preferably, not larger than 0.5 μm. When the average particle size of the inorganic filler is larger than 1 μm, surface roughness may be excessively large during roughening processing of adhesive layer 4 after curing. According to the embodiment, the average particle size is a weight average particle size measured using a laser diffraction particle size analyzer.

The epoxy resin composition may further contain other additives, such as a flame retardant, a flame retardant auxiliary, a leveling agent, or a colorant, as necessary.

The thickness of adhesive layer 4, a dimension of adhesive layer 4 in lamination direction D1, is not particularly limited, and is determined such that, when a cured material layer (cured primer layer 41 described later) obtained by curing adhesive layer 4 is formed on a surface of an insulating layer made of a cured material of prepreg 6 described later or a surface of core board 8 using metal-foil-attached adhesive sheet 1, a proper low-roughness surface can be formed by roughening a surface of the cured material layer. When the thickness of adhesive layer 4 is excessively large, not only the thickness of circuit board 9 or a laminated board (e.g., metal-foil-attached laminated board 5 and a metal-foil-attached multi-layer board as described later) which is manufactured using metal-foil-attached adhesive sheet 1 increases, but also electrical properties and mechanical properties of circuit board 9 and the laminated board may be affected. Therefore the thickness of adhesive layer 4 is preferably determined from a practical point of view. The thickness of adhesive layer 4 preferably ranges from 2.0 μM to 6.0 μm as a practical thickness.

When a surface of adhesive layer 4 made of the epoxy resin composition is roughened with a roughening agent, a surface excellent in adhesion with a wiring pattern to be formed on the surface can be formed although the surface roughness is small. Therefore, even when intervals between wires are smaller than a conventional sheet to increase the density, the wiring pattern can be accurate.

Where P1 is a peeling strength at an interface between surface 2B of metal foil 2 and surface 3A of release layer 3, and P2 is a peeling strength at an interface between surface 3B of release layer 3 and surface 4A of adhesive layer 4 after curing in metal-foil-attached adhesive sheet 1, P1 is larger than P2. That is, peeling strength P1 at the interface between surface 2B of metal foil 2 and surface 3A of peeling layer 3 for peeling surface 3A of release layer 3 from surface 2B of metal foil 2 and peeling strength P2 at the interface between surface 3B of release layer 3 and surface 4A of adhesive layer 4 after curing for peeling surface 4A of adhesive layer 4 after curing from surface 3B of release layer 3 satisfy the relationship of P1>P2. In the conventional resin-attached copper foil, it is necessary to remove the copper foil by etching when a wiring pattern is formed after forming in the build-up method. In metal-foil-attached adhesive sheet 1 according to the embodiment, peeling strengths P1 and P2 satisfy the relationship of P1>P2, and therefore, metal foil 2 and release layer 3 can be peeled and removed from later-described laminated body 10 while adhesive layer 4 after curing is kept thereon.

The magnitudes of peeling strengths P1 and P2 are not particularly limited as long as P1 is larger than P2. However, peeling strength P2 preferably ranges from 50 N/m to 150 N/m from the viewpoint of workability and mechanical stress at the time of peeling release layer 3 and cured adhesive layer 4 from each other at the interface between release layer 3 and cured adhesive layer 4. Peeling strength P1 is not particularly limited as long as peeling strength P1 is larger than peeling strength P2. But, for reliably peeling release layer 3 from cured adhesive layer 4 at the interface between layers 3 and 4, peeling strength P1 is preferably sufficiently larger than peeling strength P2, and the difference (P1-P2) is preferably larger than 50 N/m. It is considered that the substantial upper limit of peeling strength P1 ranges from 1800 N/m to 2000 N/m.

Specific peeling strength P2 can be measured in accordance with, for example, the method specified in JIS Standard No. C6481. FIG. 1B is a schematic plan view of a test piece of metal-foil-attached adhesive sheet 1 for measuring peeling strength P2. FIG. 1C is a schematic front view of metal-foil-attached adhesive sheet 1 measuring peeling strength P2 of the test piece. As shown in FIG. 1B, a rectangular test piece of metal-foil-attached adhesive sheet 1 having a length of 100 mm and a width of 10±0.1 mm is prepared. Next, adhesive layer 4 of the test piece is placed on support plate 20, and heating and pressure forming is performed at a predetermined temperature and a predetermined pressure for a predetermined time to bond and fix the test piece to support plate 20. Adhesive layer 4 is cured to be cured primer layer 41. As shown in FIG. 1C, one end of the test piece is pinched up, and pulled up substantially perpendicularly to support plate 20 at a speed of 50 mm/minute, so that metal foil 2 and release layer 3 are peeled from cured primer layer 41. A force required for the peeling is measured as peeling strength P2.

Measurement of peeling strength P1 may be omitted when it is evident that peeling strength P1 is sufficiently larger than peeling strength P2. When a magnitude of peeling strength P1 is measured, it is difficult to peel metal foil 2 from release layer 3 at the interface between metal foil 2 and release layer 3 since peeling strength P1 is larger than peeling strength P2 in metal-foil-attached adhesive sheet 1. Therefore, a P1 measuring test piece for measuring peeling strength P1 is prepared as follows. As the P1 measuring test piece, for example, the piece is prepared by forming release layer 3 on metal foil 2, and instead of providing adhesive layer 4, roughening a surface of release layer 3, and bonding and fixing release layer 3 onto support plate 20 by, e.g. a pressure sensitive adhesive tape. Alternatively, the piece is prepared by forming two metal foils 2 integrated with release layer 3 between two metal foils 2, and bonding and fixing them to support plate 20. By conducting a peeling test by the method shown in FIG. 1C using the P1 measuring test piece prepared as described above, at least an approximate magnitude of peeling strength P1 can be measured.

A method of manufacturing metal-foil-attached adhesive sheet 1 in accordance with the embodiment will be described below.

A varnish of a resin composition for forming release layer 3 (release layer varnish) and a varnish of a thermosetting resin composition for forming adhesive layer 4 (adhesive layer varnish) are prepared.

The release layer varnish is prepared by blending the foregoing matrix resin and silicone compound, and a curing agent etc. as necessary. The varnish may not contain solvent when the matrix resin is a liquid, or a solvent may be added to form a varnish.

The adhesive layer varnish is prepared by, for example, blending components (A) to (C) with other additives as necessary. The varnish may not contain solvent when component (A) etc. is a liquid, or a solvent may be added to form a varnish.

Examples of the solvent to be used for preparing the release layer varnish and the adhesive layer varnish may include aromatic hydrocarbons, such as benzene and toluene, amides, such as N,N-dimethylformamide (DMF), ketones, such acetone and methyl ethyl ketone, alcohols, such as methanol and ethanol, and cellosolves. Only one of these solvents may be used, or two or more of these solvents may be used in combination.

The release layer varnish is first applied to surface 2B (preferably a mat surface) of metal foil 2, and then, is heated and dried at a temperature ranging from 100° C. to 150° C. for a duration ranging from 1 minute to 5 minutes to remove the solvent, thereby forming release layer 3 which is in a cured state. Metal foil 2 provided with release layer 3 (a metal foil with a release layer) may be temporarily wound to form a roll and stored in the form of the roll.

Next, the adhesive layer varnish is applied onto surface 3B of release layer 3 formed on surface 2B of metal foil 2. Then, the applied varnish is heated and dried at a temperature ranging from 100° C. to 200° C. for a duration ranging from 1 minute to 5 minutes to remove the solvent in the adhesive layer varnish, thereby forming adhesive layer 4 in a semi-cured state. Thus, metal-foil-attached adhesive sheet 1 shown in FIG. 1A can be manufactured.

Here, the release layer varnish and the adhesive layer varnish can be applied using, for example, a comma coater, a blade coater, a lip coater, a rod coater, a squeeze coater, a reverse coater, a transfer roll coater, a gravure coater or a spray coater.

A method of manufacturing a circuit board in accordance with the embodiment will be described below. According to the embodiment, a circuit board can be manufactured by a build-up method using metal-foil-attached adhesive sheet 1.

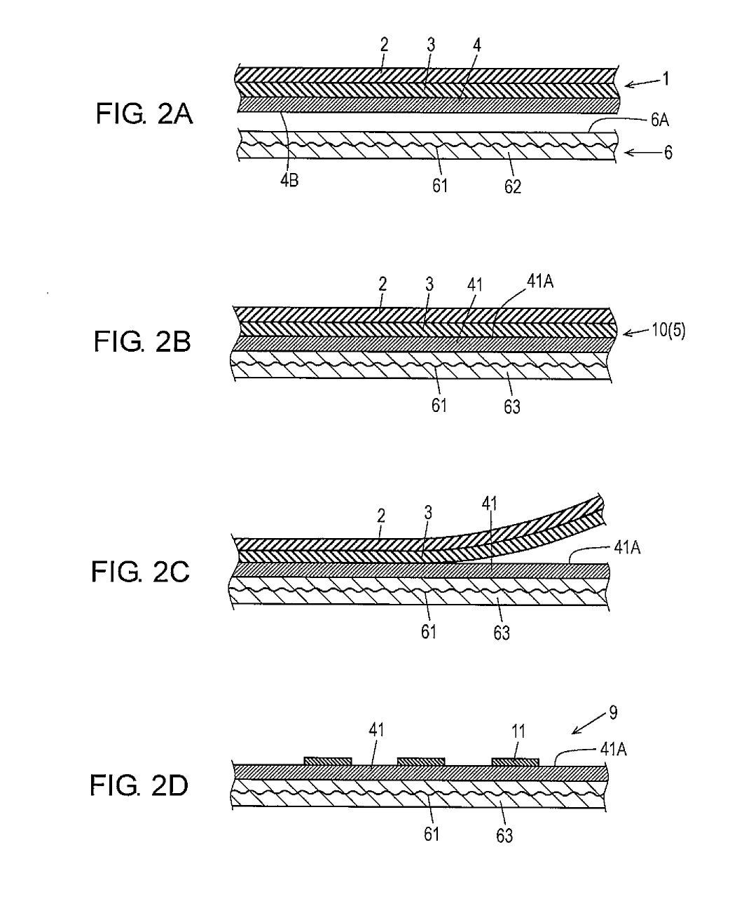

FIGS. 2A to 2D are schematic sectional views of the circuit board in accordance with the embodiment for illustrating the method of manufacturing the circuit board. FIGS. 2A and 2B illustrate a lamination/forming step, FIG. 2C illustrates a peeling step, and FIG. 2D illustrates a circuit forming step.

First, as shown in FIG. 2A, surface 4B of adhesive layer 4 of metal-foil-attached adhesive sheet 1 is placed on prepreg 6. At this moment, surface 4B of adhesive layer 4 of metal-foil-attached adhesive sheet 1 may be placed on one prepreg 6, or may be stacked on plural stacked prepregs 6. A metal foil, such as a copper foil, may be disposed opposite to metal-foil-attached adhesive sheet 1 across prepreg 6. Prepreg 6 is not particularly limited, and a layer of semi-cured resin 62 which is formed by impregnating substrate 61, such as a glass cloth, with a thermosetting resin composition containing a thermosetting resin, such as an epoxy resin, can be used. The thermosetting resin composition with which substrate 61 is impregnated is preferably filled with an inorganic filler, such as silica, with a high density since the thermal expansion coefficient of the circuit board can be reduced.

Metal-foil-attached adhesive sheet 1 and prepreg 6 are subjected to heating and pressure forming, for example, at a temperature ranging from 130° C. to 200° C. and a predetermined pressure for a predetermined time, thus providing metal-foil-attached laminated board 5 as laminated body 10. At this moment, since the support that supports metal-foil-attached adhesive sheet 1 is metal foil 2 and metal-foil-attached adhesive sheet 1 can endure the foregoing high forming temperature, a lamination step needed for conventional adhesive films having a resin film as a support can be omitted, so that laminated body 10 can be obtained by lamination/forming at once. Laminated body 10 is metal-foil-attached laminated board 5 in which adhesive layer 4 of metal-foil-attached adhesive sheet 1 is cured and integrated with prepreg 6. Adhesive layer 4 is cured to be a cured primer layer 41, and semi-cured resin 62 of prepreg 6 is cured to be a cured resin 63.

Next, as shown in FIG. 2C, release layer 3 is peeled from adhesive layer 4 after curing (i.e., cured primer layer 41) at the interface between release layer 3 and adhesive layer 4 to peel and remove metal foil 2 and release layer 3 from laminated body 10, so that surface 41A of cured primer layer 41 is exposed. Since peeling strength P1 is larger than peeling strength P2 as described above, the peeling can be easily performed, so that an etching step for removing metal foil 2 is unnecessary. Moreover, a post-curing step is unnecessary since adhesive layer 4 becomes the cured primer layer 41.

Next, as shown in FIG. 2D, surface 41A of cured primer layer 41 exposed in the peeling step is plated to form a circuit. Fine wiring pattern 11 in which a line-and-space (LIS) that includes a width L of a line and a width S of a space between lines is about 10 μm/10 μm can be formed on surface 41A of cured primer layer 41.

When exposed surface 41A of cured primer layer 41 is roughened with the following roughening liquid before the foregoing plating processing is performed, fine wiring pattern 11 can be formed on surface 41A of cured primer layer 41 with high adhesion.

The roughening liquid is not particularly limited as long as it contains one or both of an acid and an oxidant. For example, surface 41A of cured primer layer 41 can be roughened with an oxidant, such as a permanganate, a bichromate, ozone, hydrogen peroxide/sulfuric acid, or nitric acid.

As a specific example of the roughening liquid, a set of three products: “CIRCUPOSIT MLB211” manufactured by Rohm and Haas Company, “CIRCUPOSIT MLB213” manufactured by Rohm and Haas Company and “CIRCUPOSIT MLB216” manufactured by Rohm and Haas Company can be used. The roughening processing with the roughening liquid can be performed by peeling and removing metal foil 2 and release layer 3 from laminated body 10, and then processing exposed cured primer layer 41 with the roughening liquid, and roughening processing can be performed plural times while the kind of the roughening liquid is changed. The temperature of the roughening liquid may range from 40° C. to 90° C., and the processing time can range from 1 minute to 30 minutes.

When a set of three products: “CIRCUPOSIT MLB211” manufactured by Rohm and Haas Company, “CIRCUPOSIT MLB213” manufactured by Rohm and Haas Company and “CIRCUPOSIT MLB216” manufactured by Rohm and Haas Company is used as the roughening liquid, cured primer layer 41 exposed by removing metal foil 2 and release layer 3 from laminated body 10 is first immersed in “CIRCUPOSIT MLB211”, then immersed in “CIRCUPOSIT MLB213”, and finally processed with “CIRCUPOSIT MLB216”, and thus roughening processing can be performed.

Then, wiring pattern 11 is formed by a known semi-additive method on surface 41A of cured primer layer 41 subjected to roughening processing, thereby providing circuit board 9. Thus, after laminated body 10 is obtained using metal-foil-attached adhesive sheet 1, metal foil 2 and release layer 3 are removed from laminated body 10, exposed surface 41A of cured primer layer 41 is plated to form fine wiring pattern 11.

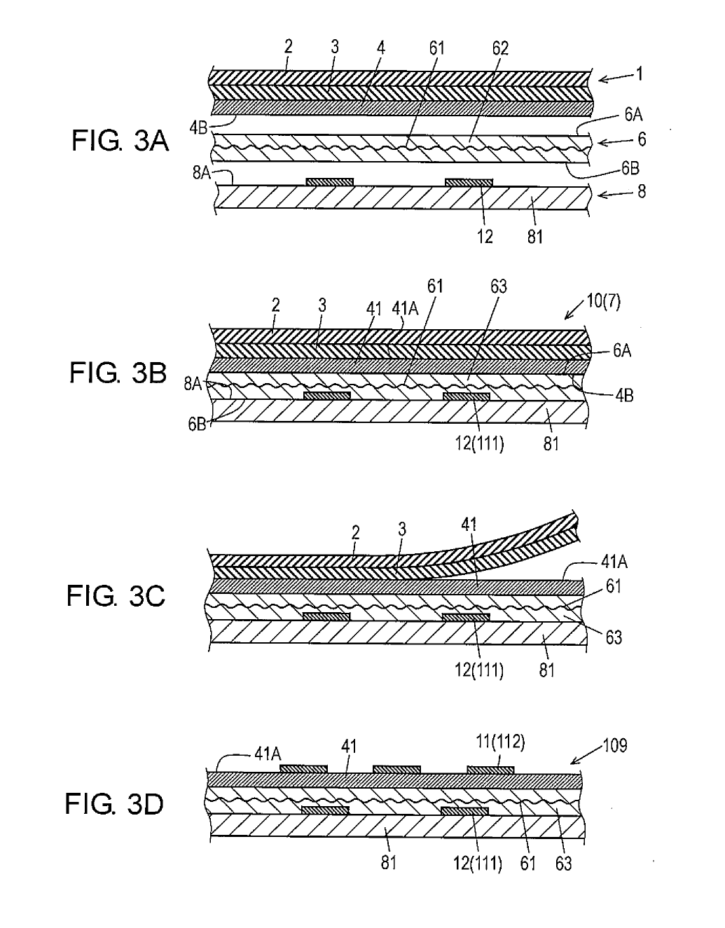

FIGS. 3A to 3D are schematic sectional views of the circuit board in accordance with the embodiment for illustrating another method of manufacturing the circuit board. FIGS. 3A and 3B show a lamination/forming step, FIG. 3C shows a peeling step, and FIG. 3D shows a circuit forming step.

First, as shown in FIG. 3A, adhesive layer 4 of metal-foil-attached adhesive sheet 1 overlapped core board 8 across prepreg 6. That is, surface 4B of adhesive layer 4 of metal-foil-attached adhesive sheet 1 is situated on surface 6A of prepreg 6, and surface 8A of core board 8 is situated on surface 6B of prepreg 6 opposite to surface 6A. As prepreg 6, one similar to that described above can be used. Core board 8 includes, for example, inner-layer circuit board 81, and wiring pattern 12 formed on surface 8A of inner-layer circuit board 81. According to the embodiment, inner-layer circuit board 81 may be used as core board 8. Prepreg 6 is placed between adhesive layer 4 of metal-foil-attached adhesive sheet 1 and surface 8A of core board 8 on which wiring pattern 12 is provided.

Metal-foil-attached adhesive sheet 1, prepreg 6 and core board 8 are stacked in this order, and subjected to heating and pressure forming, for example, at a temperature ranging from 130° C. to 200° C. and a predetermined pressure for a predetermined time, and thus metal-foil-attached multi-layer board 7 can be obtained as laminated body 10. At this moment, since the support that supports metal-foil-attached adhesive sheet 1 is metal foil 2 and metal-foil-attached adhesive sheet 1 can endure the foregoing high forming temperature, a lamination step needed for conventional adhesive films having a resin film as a support can be omitted, so that laminated body 10 can be obtained by batch lamination/forming. Laminated body 10 is metal-foil-attached multi-layer board 7 in which adhesive layer 4 of metal-foil-attached adhesive sheet 1 is cured and integrated with core board 8 with prepreg 6 provided between adhesive layer 4 and core board 8. Adhesive layer 4 is cured to be cured primer layer 41, and semi-cured resin 62 of prepreg 6 is cured to be cured resin 63. Wiring pattern 12 of core board 8 is placed inside cured resin 63, and becomes inner-layer pattern 111.

Next, as shown in FIG. 3C, surface 3B of release layer 3 is peeled from surface 41A of cured primer layer 41 at the interface between surface 3B of release layer 3 and surface 41A of cured primer layer 41 to peel and remove metal foil 2 and release layer 3 from laminated body 10. Since peeling strength P1 is larger than peeling strength P2, as described above, the peeling can be easily performed, so that an etching step for removing metal foil 2 is unnecessary. Moreover, a post-curing step is unnecessary since adhesive layer 4 already becomes cured primer layer 41.

Next, as shown in FIG. 3D, surface 41A of cured primer layer 41 exposed in the peeling step is plated to form a circuit. Fine wiring pattern 11 having a line-and-space (LIS) of about 10 μm/10 μm can be thereby formed on surface 41A of cured primer layer 41 as outer-layer pattern 112.

When surface 41A of cured primer layer 41 is subjected to roughening processing with the foregoing roughening liquid before the foregoing plating processing is performed, fine wiring pattern 11 can be formed on cured primer layer 41 with high adhesion.

Then, wiring pattern 11 is formed as outer-layer pattern 112 by a known semi-additive method on surface 41A of cured primer layer 41 subjected to roughening processing, and thus circuit board 109 can be obtained. Inner-layer pattern 111 and outer-layer pattern 112 may be electrically connected to each other via a through-hole or a blind via-hole. Thus, laminated body 10 is obtained using metal-foil-attached adhesive sheet 1. After that, metal foil 2 and release layer 3 are removed from laminated body 10, and then, exposed cured primer layer 41 is plated to form fine wiring pattern 11.

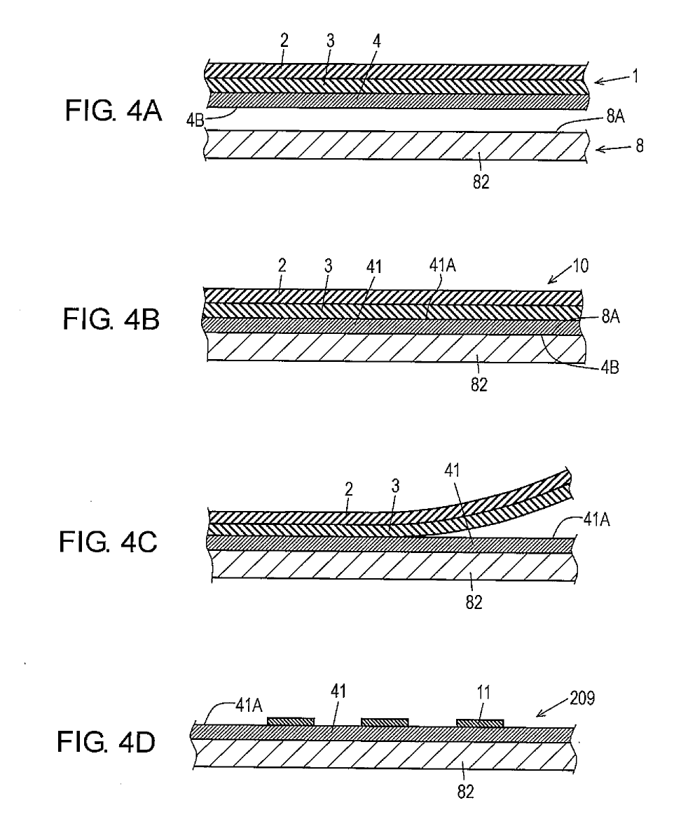

FIGS. 4A to 4D are schematic sectional views of a circuit board in accordance with the embodiment for illustrating still another method of manufacturing the circuit board. FIGS. 4A and 4B show a lamination/forming step, FIG. 4C shows a peeling step, and FIG. 4D shows a circuit forming step.

First, as shown in FIG. 4A, surface 4B of adhesive layer 4 of metal-foil-attached adhesive sheet 1 is placed on surface 8A of core board 8. As core board 8, for example, known uncladded board 82 can be used. Uncladded board 82 is an insulating board having a surface not covered with a metal foil. In accordance with the embodiment, uncladded board 82 is used as core board 8.

Metal-foil-attached adhesive sheet 1 and core board 8 are stacked on each other, and subjected to heating and pressure forming, for example, at a temperature ranging from 130° C. to 200° C. and a predetermined pressure for a predetermined time, thus providing laminated body 10. At this moment, since the support that supports metal-foil-attached adhesive sheet 1 is metal foil 2 and metal-foil-attached adhesive sheet 1 can endure the foregoing high forming temperature, a lamination step needed for conventional adhesive films having a resin film as a support can be omitted, so that laminated body 10 can be obtained by batch lamination/forming. In laminated body 10, adhesive layer 4 of metal-foil-attached adhesive sheet 1 is cured and integrated with uncladded board 82. Adhesive layer 4 is cured into cured primer layer 41.

Next, as shown in FIG. 4C, surface 3B of release layer 3 is peeled from surface 41A of cured primer layer 41 at the interface between surface 3B of release layer 3 and surface 41A of cured primer layer 41 to peel and remove metal foil 2 and release layer 3 from laminated body 10. Since peeling strength P1 is larger than peeling strength P2, as described above, the peeling can be easily performed, so that an etching step for removing metal foil 2 is unnecessary. Moreover, a post-curing step is unnecessary since adhesive layer 4 already becomes cured primer layer 41.

Next, as shown in FIG. 4D, surface 41A of cured primer layer 41 exposed in the peeling step is plated to form a circuit. Fine wiring pattern 11 having a line-and-space (LIS) of about 10 μm/10 μm can be thereby formed on surface 41A of cured primer layer 41.

When surface 41A of cured primer layer 41 is subjected to roughening processing with the foregoing roughening liquid before the foregoing plating processing is performed, fine wiring pattern 11 can be formed on surface 41A of cured primer layer 41 with high adhesion.

Then, wiring pattern 11 is formed by a known semi-additive method on surface 41A of cured primer layer 41 subjected to roughening processing, and thus circuit board 209 can be obtained. In this way, laminated body 10 is obtained using metal-foil-attached adhesive sheet 1. After that, metal foil 2 and release layer 3 are removed from laminated body 10, and then, exposed cured primer layer 41 is plated to form fine wiring pattern 11.

An example of forming wiring pattern 11 by a semi-additive method will be described below. First, laminated body 10 after subjecting cured primer layer 41 to roughening processing as described above is provided. A through hole and a non-through hole for forming a through-hole and a blind via-hole are formed in laminated body 10 as necessary using a drill or a laser. Next, an electroless plating processing is performed to form an electroless plating, such as a copper electroless plating, on surface 41A of cured primer layer 41, and a plating resist is then formed on a portion where a circuit is not formed. Then, electroless plating processing is performed to form an electroplating, such as copper electroplating, on a portion where a plating resist is not formed, and the plating resist is then peeled. The electroless plating exposed by peeling the plating resist is removed by a quick etching method (flush etching), and thus wiring pattern 11 can be formed on surface 41A of cured primer layer 41. An electroless plating and an electroplating are formed on inner surfaces of the through hole and non-through hole, and a through-hole and a blind via-hole for electrical connection to an inner-layer circuit and a back surface side circuit are thereby formed. After-curing may be appropriately performed.

Thus, metal-foil-attached adhesive sheet 1 in accordance with the embodiment allows wiring pattern 11 of the circuit board to be fine, and allows batch lamination/forming to be performed, so that the lamination step and the post-curing step can be omitted, and further the etching step can be omitted, hence reducing manufacturing costs of the circuit board.

Thus, metal-foil-attached adhesive sheet 1 in accordance with the embodiment can be placed on a prepreg or core board 8 and subjected to heating and pressure forming to obtain laminated body 10. That is, since the support that supports metal-foil-attached adhesive sheet 1 is metal foil 2, laminated body 10 can be obtained by batch lamination/forming without performing the lamination step, and therefore, the post-curing step is unnecessary. Metal foil 2 and release layer 3 are removed from laminated body 10, adhesive layer 4 exposed after curing is plated to form fine wiring pattern 11. At this moment, peeling strength P1 is larger than peeling strength P2, and therefore, when metal foil 2 is peeled and removed from laminated body 10, release layer 3 and adhesive layer 4 (41) after curing are separated from each other at the interface between release layer 3 and adhesive layer 4 (41), so that adhesive layer 4 (41) after curing can be exposed. Therefore, removal of metal foil 2 from laminated body 10 can be performed by mechanical processing of peeling metal foil 2 rather than an etching step that increases processing costs. Moreover, release layer 3 does not remain on exposed surface 41A of adhesive layer 4 (cured primer layer 41) after curing.

Thus, metal-foil-attached adhesive sheet 1 in accordance with the embodiment allows wiring pattern 11 of the circuit board to be fine, and allows batch lamination/forming to be performed, hence reducing manufacturing costs of the circuit board.

What is claimed is:

1. A metal-foil-attached adhesive sheet comprising:
a metal foil;
a release layer provided on the metal foil; and
an adhesive layer provided on the release layer and made of a thermosetting resin composition which is semi-cured,
wherein a surface of the metal foil on which the release layer is provided has a ten-point roughness Rz ranging from 0.5 μm to 2.0 μm,
wherein a thickness of the release layer is larger than the ten-point average roughness Rz of the surface of the metal foil on which the release layer is provided,
wherein a peeling strength P1 at an interface between the metal foil and the release layer and a peeling strength P2 at an interface between the release layer and the adhesive layer which is cured satisfy P1>P2, and
wherein the metal-foil-attached adhesive sheet is configured to provide a laminated body for manufacturing of a circuit board by placing the adhesive layer on a prepreg or a core board, and heating and pressure-forming the laminated body to cure the adhesive layer, and the laminated body is configured to have the release layer is peeled from the adhesive layer after curing at an interface between the release layer and the adhesive layer after curing.

2. The metal-foil-attached adhesive sheet according to claim 1, wherein the thickness of the release layer ranges from 0.5 μm to 5.0 μm.

3. The metal-foil-attached adhesive sheet according to claim 1, wherein the release layer has a softening point not lower than 150° C.

4. The metal-foil-attached adhesive sheet according to claim 1, wherein the peeling strength P2 ranges from 50 N/m to 150 N/m.

5. The metal-foil-attached adhesive sheet according to claim 1,
wherein the release layer contains a matrix resin and a silicone compound, and
wherein a content of the silicone compound ranges from 5.0 wt. % to 40.0 wt. % with respect to a whole amount of the release layer.

6. The metal-foil-attached adhesive sheet according to claim 5,
wherein the matrix resin contains an epoxy resin, and
wherein the silicone compound is compatible with or dispersed in the matrix resin.

7. A metal-foil-attached laminated board comprising:
the metal-foil-attached adhesive sheet according to claim 1; and
a prepreg provided on the adhesive layer of the metal-foil-attached adhesive sheet, the adhesive layer being cured and integrated with the prepreg.

8. A metal-foil-attached multi-layer board comprising:
the metal-foil-attached adhesive sheet according to claim 1; and
a core board provided on the adhesive layer of the metal-foil-attached adhesive sheet, wherein the adhesive layer is cured and integrated with the core board.

9. A method of manufacturing a circuit board, comprising:
a lamination/forming step of providing a laminated body by placing the adhesive layer of the metal-foil-attached adhesive sheet according to claim 1 on a prepreg or a core board, and heating and pressure forming the metal-foil-attached adhesive sheet on the prepreg or the core board;
a peeling step of peeling and removing the metal foil and the release layer from the laminated body by peeling the release layer and the adhesive layer after curing from each other at an interface between the release layer and the adhesive layer after curing; and
a circuit forming step of forming a circuit by plating a surface of the adhesive layer after curing which is exposed in the peeling step.
